(19) United States
(12) Patent Application Publication
(10) Pub. No.: US 2009/0146127 A1
(43) Pub. Date: Jun. 11, 2009

(54) PHASE CHANGE MEMORY

(75) Inventors: Ming-Jeng Huang, Taichung City (TW); Yung-Fa Lin, Hsinchu City (TW)

Correspondence Address: QUINTERO LAW OFFICE, PC, 2210 MAIN STREET, SUITE 200, SANTA MONICA, CA, 90405, US

(73) Assignees: INDUSTRIAL TECHNOLOGY RESEARCH INSTITUTE, HSINCHU (TW); POWERCHIP SEMICONDUCTOR CORP., HSIN-CHU (TW); NANYA TECHNOLOGY CORPORATION, TAOYUAN (TW); PROMOS TECHNOLOGIES INC.., HSINCHU (TW); WINBOND ELECTRONICS CORP., HSINCHU (TW)

(21) Appl. No.: 12/135,041

(22) Filed: Jun. 6, 2008

(30) Foreign Application Priority Data
Dec. 11, 2007 (TW) TW96147212

(51) Int. Cl. H01L 47/00

(52) U.S. Cl. 257/3; 257/E47.001

(57) ABSTRACT

Phase change memories comprising a top electrode, a phase change element, a plurality of via holes allocated between the top electrode and the phase change element, at least four heaters aiming at different regions of the phase change element, and a plurality of bottom electrodes and transistors corresponding to the heaters. The bottom electrodes are respectively coupled to the heaters. Regarding the transistors, their first terminals are respectively coupled to the bottom electrodes, their control terminals are used for coupling to word lines, and their second terminals are used for coupling to bit lines. In an embodiment with four heaters, the regions the heaters aimed at the phase change element form a 2×2 storage array.

### CROSS REFERENCE TO RELATED APPLICATIONS

This application claims priority of Taiwan Patent Application No. 96147212, filed on Dec. 11, 2007, the entirety of which is incorporated by reference herein.

### BACKGROUND OF THE INVENTION

1. Field of the Invention

The present invention relates to memories and particularly relates to Phase Change Memories (PCMs).

2. Description of the Related Art

FIG. 1 illustrates a conventional phase change memory, comprising three storage cells controlled by a word line WLₙ and bit lines BLₘ₋₁, BLₘ and BLₘ₊₁. The figure comprises two parts: one is symbolized by 102, which is the cross-section view of a phase change device of the phase change memory; and the other part is a circuit 104 comprising transistors controlling the phase change device 102. To read/write the storage cell corresponding to the word line WLₙ and the bit line BLₘ₋₁, the conventional technique provides a top electrode 106, a via hole 108, a protective layer 110, a phase change element 112, a heater 114, a bottom electrode 116 and a transistor 118. The top electrode 106 is coupled to the bit line BLₘ₋₁. The transistor 118 comprises a first terminal coupled to the bottom electrode 116, a second terminal coupled to a reference voltage source V_{ref} (such as ground), and a control terminal coupled to the word line WLₙ. When the storage cell is selected to be read/written, the signal at the word line WLₙ enables the transistor 118 so that a current path is provided. As shown in FIG. 1, the current path is formed by bit line BLₘ₋₁, the top electrode 106, the via hole 108, the protective layer 110, the phase change element 112, the heater 114, the bottom electrode 116 and the transistor 118. Thus, the heater 114 is able to change the phase of the phase change element 112. In a write operation, the heater 114 forces power into the phase change element 112 to set it to an amorphous state or a crystalline state. The phase change element has high impedance in the amorphous state and has low impedance in the crystalline state. When the phase change element has high impedance, the data stored in the corresponding storage cell is ‘1’. When the phase change element has low impedance, the data stored in the corresponding storage cell is ‘0’.

Referring to FIG. 1, bit line signals BLₘ₋₁, BLₘ and BLₘ₊₁ are inputted to the phase change memory via the top electrodes. Each storage cell requires an exclusive top electrode for receiving the corresponding bit line. In addition, the conventional phase change memory technique further provides an exclusive via hole, protective layer, phase change element, heater, bottom electrode and transistor for each storage cell. As shown in FIG. 1, the phase change elements for different storage cells are separate and disconnected. With the advanced development of semiconductors, memory capacity has dramatically increased and the size of the memory has shrunk. Thus, the space between the phase change elements is very narrow and it is difficult to produce the isolated phase change elements. In efforts to precisely separate the phase change elements of different storage cells, expensive lithography techniques, such as ArF, has been adopted in the photo-lithography process. In addition, because the size of the isolated phase change elements is too small, the quality of the conventional phase change memory is also affected by plasma-induced damages occurring during the etching process.

Thus, novel phase change memories with large capacity and a low price are called for.

### BRIEF SUMMARY OF THE INVENTION

The invention provides phase change memories. The phase change memory comprises a top electrode, a phase change element, a plurality of via holes, four heaters, four bottom electrodes, and four transistors. The via holes are allocated between the top electrode and the phase change element. The heaters aim at different regions of the phase change element. The phase change regions aimed by the heaters form a 2×2 storage array. The bottom electrodes, the heaters and the transistors have a one-to-one relationship. The bottom electrodes are coupled to their corresponding heaters and transmit signals into their corresponding heaters. Each of the transistors comprises a first terminal, a second terminal and a control terminal. The first terminals of the transistors are respectively coupled to the bottom electrodes. For the first transistor, the second terminal receives a first bit line signal and the control terminal receives a first word line signal. For the second transistor, the second terminal receives a second bit line signal and the control terminal receives the first word line signal. For the third transistor, the second terminal receives the first bit line signal and the control terminal receives a second word line signal. For the fourth transistor, the second terminal receives the second bit line signal and the control terminal receives the second word line signal.

In other embodiments of the invention, the phase change memory comprises a top electrode, a plurality of via holes, a phase change element, a plurality of heaters, a plurality of bottom electrodes and a plurality of transistors. The via holes are allocated between the top electrode and the phase change element. The heaters aim at different regions of the phase change element. The bottom electrodes have a one-to-one relationship with the heaters, and each is couple to its corresponding heater. The transistors have a one-to-one relationship with the bottom electrodes, and each comprises a first terminal, a second terminal and a control terminal. The transistors are coupled to their corresponding bottom electrodes via their first terminals. The second terminals of the transistors are used for receiving the bit line signals of the phase change memory. The control terminals of the transistors are used for receiving the word line signal of the phase change memory.

The above and other advantages will become more apparent with reference to the following description taken in conjunction with the accompanying drawings.

### BRIEF DESCRIPTION OF THE DRAWINGS

The invention can be more fully understood by reading the subsequent detailed description and examples with references made to the accompanying drawings, wherein:

FIG. 1 illustrates a conventional phase change memory;

FIG. 2 illustrates an embodiment of the phase change memory of the invention; and

FIG. 3 illustrates another embodiment of the phase change memory of the invention.

### DETAILED DESCRIPTION OF THE INVENTION

The following description shows some embodiments carrying out the invention. This description is made for the purpose of illustrating the general principles of the invention and should not be taken in a limiting sense. The scope of the invention is best determined by reference to the appended claims.

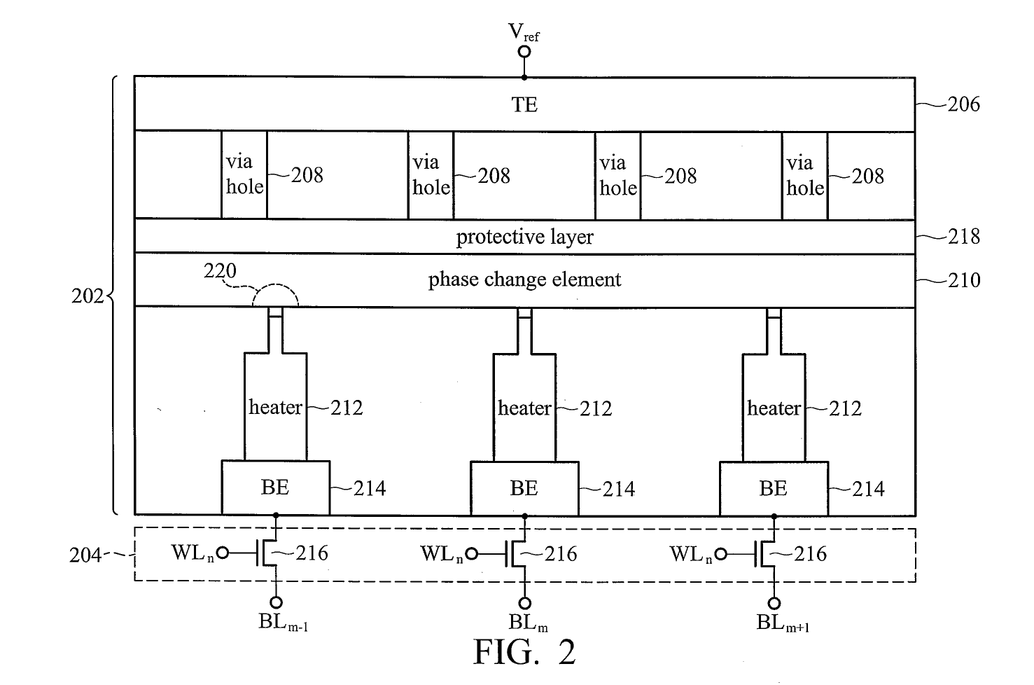

FIG. 2 illustrates an embodiment of the phase change memory of the invention, comprising three storage cells controlled by a word line WLₙ and bit lines BLₘ₋₁, BLₘ and BLₘ₊₁. FIG. 2 comprises two parts: one is a phase change device 202 of the phase change memory, which is shown by a cross-section view; and the other part is a circuit 204 comprising transistors controlling the phase change device. The phase change memory shown in FIG. 2 comprises a top electrode 206, a plurality of via holes 208, a phase change element 210, a plurality of heaters 212, a plurality of bottom electrodes 214 and a plurality of transistors 216. The via holes 208 are allocated between the top electrode 206 and the phase change element 210. The heaters 212 aim at different regions of the phase change element 210. The bottom electrodes 214 have a one-to-one relationship with the heaters 212, and each is coupled to its corresponding heater. The transistors 216 have a one-to-one relationship with the bottom electrodes 214, and each comprises a first terminal, a second terminal and a control terminal. The transistors 216 are coupled to their corresponding bottom electrodes 214 via their first terminals. The second terminals of the transistors 216 are used for receiving the bit line signals of the phase change memory (referring to FIG. 2, the second terminals of the three transistors 216 are coupled to the bit lines BLₘ₋₁, BLₘ and BLₘ₊₁, respectively). The control terminals of the transistor 216 are used for receiving the word line signal of the phase change memory (referring to FIG. 2, the control terminals of the three transistors 216 are all coupled to the word line WLₙ). The aimed phase change regions (such as region 220 corresponding to WLₙ and BLₘ₋₁) represent storage cells of the phase change memory. In a write operation, the heater forces power into the phase change region it aims at, thus, the aimed phase change region is set to an amorphous state or a crystalline state. When the aimed phase change region is set to the amorphous state, the data stored in the corresponding storage cell is ‘1’. When the aimed phase change region is set to the crystalline state, the data stored in the corresponding storage cell is ‘0’.

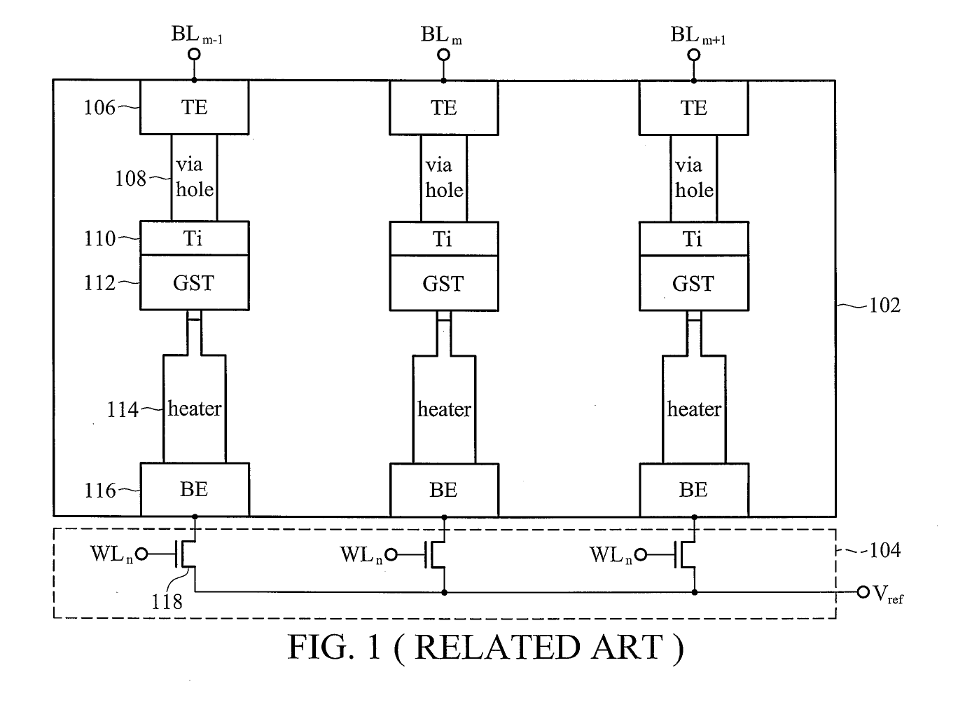

Instead of receiving the bit line signals via the top electrodes (as in the conventional technique shown in FIG. 1), the invention receives the bit line signals via the second terminals of the transistors 216. Referring to FIG. 2, instead of comprising a plurality of top electrodes for different bit lines, the storage cells of the invention share a single top electrode 206. In this embodiment, the top electrode 206 is coupled to a reference voltage source V_{ref}. The reference voltage source V_{ref} may be ground.

Referring to FIG. 2, the storage cells of the phase change memory of the invention share a single phase change element (210). Because the invention does not have to isolate the phase change element as in FIG. 1, the phase change element of the invention (210) can be produced by a relatively inexpensive photo-lithography process, such as a KrF process, instead of an expensive photo-lithography process such as an ArF process. Furthermore, plasma-induced damage is reduced since the size of the phase change element 210 is much greater than the size of the isolated phase change elements that are adopted in conventional techniques.

In the conventional technique shown in FIG. 1, the via holes have a one-to-one relationship with the storage cells and are used for transmitting electrical carriers between the corresponding top electrodes and the corresponding phase change elements. In the invention (referring to FIG. 2), however, different storage cells share a single phase change element 210 and a single top electrode 206, so that the via holes 208 do not have to be individually set for the storage cells. Thus, the via holes of the invention are not limited to having a one-to-one relationship with the storage cells.

In some embodiments, the phase change element 210 is further covered by a protective layer 218. Referring to FIG. 2, the protective layer 218 is allocated between the phase change element 210 and the via holes 208.

The following describes an example of driving a storage cell of the invention. To drive the storage cell coupled to the word line WLₙ and the bit line BLₘ₋₁, the corresponding transistor is turned on by the word line WLₙ. When the transistor is turned on, the signal transmitted by the bit line BLₘ₋₁ is transmitted into the storage cell to drive the corresponding heater to heat the aimed phase change region 220 to an amorphous state or a crystalline state. When the phase change region 220 is in the amorphous state, the data stored in the storage cell is ‘1’. When the phase change region 220 is in the crystalline state, the data stored in the storage cell is ‘0’.

The phase change element 210 may comprise GeSbTe (as known as GST) or other compounds having phase change capability. The protective layer 218 may comprise TiN or Ti/TiN or other similar compound.

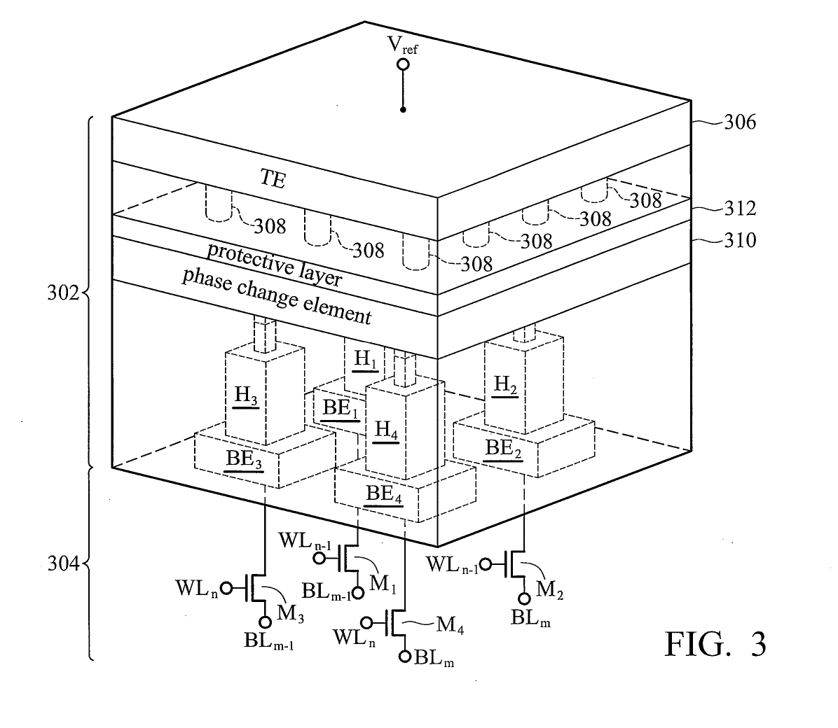

FIG. 3 illustrates another embodiment of the phase change element of the invention, which comprises four storage cells controlled by the word lines WLₙ₋₁ and WLₙ and bit lines BLₘ₋₁ and BLₘ. The four storage cells form a 2×2 storage array. FIG. 3 comprises two parts: one is a phase change device 302 shown in a cross-section view, and the other part is a circuit 304 comprising transistors controlling the phase change device 302. In this embodiment, the phase change memory comprises a top electrode 306, a plurality of via holes 308, a phase change element 310, four heaters (H₁, H₂, H₃ and H₄), four bottom electrodes (BE₁, BE₂, BE₃ and BE₄), and four transistors (M₁, M₂, M₃ and M₄). The via holes 308 are allocated between the top electrode 306 and the phase change element 310. The heaters H₁, H₂, H₃ and H₄ aim at different regions of the phase change element 310. The bottom electrodes BE₁, BE₂, BE₃ and BE₄ are coupled to the heaters H₁, H₂, H₃ and H₄, respectively, to receive and transmit signals into the heaters H₁, H₂, H₃ and H₄. The transistors M₁, M₂, M₃ and M₄ have a one-to-one relationship with the bottom electrodes BE₁, BE₂, BE₃ and BE₄, and each comprises a first terminal, a second terminal and a control terminal. The first terminals of the transistors M₁, M₂, M₃ and M₄ are coupled to their bottom electrodes, respectively. Referring to FIG. 3, second terminal of the first transistor M₁ receives the bit line signal BLₘ₋₁ and the control terminal of the first transistor M₁ receives the word line signal WLₙ₋₁. The second terminal of the second transistor M₂ receives the bit line signal BLₘ and the control terminal of the second transistor M₂ receives the word line signal WLₙ₋₁. The second terminal of the third transistor M₃ receives the bit line signal BLₘ₋₁ and the control terminal of the third transistor M₃ receives the word line signal WLₙ. The second terminal of the fourth transistor M₄ receives the bit line signal BLₘ and the control terminal of the fourth transistor M₄ receives the word line signal WLₙ. The phase change regions aimed by the heaters H₁, H₂, H₃ and H₄ form a 2×2 storage array. In a write operation, the heaters force power into the phase change regions they aimed at to set them to an amorphous state or a crystalline state. When the aimed phase change region is in the amorphous state, the data stored in the corresponding storage cell is ‘1’. When the aimed phase change region is in the crystalline state, the data stored in the corresponding storage cell is ‘0’.

The following describes an example of driving a storage cell of the embodiment shown in FIG. 3. To write data into the storage cell driven by the word line WLₙ and the bit line BLₘ₋₁, the word line WLₙ enables the transistor M₃ to transmit the bit line signal BLₘ₋₁ into the heater H₃ to heat the phase change region aimed by the heater H₃, so that the aimed phase change region is set to an amorphous state or a crystalline state. When the aimed phase change region is in the amorphous state, the data stored in the storage cell controlled by the word line WLₙ and the bit line BLₘ₋₁ is ‘1’. When the aimed phase change region is in the crystalline state, the data stored in the storage cell controlled by the word line WLₙ and the bit line BLₘ₋₁ is ‘0’.

In some embodiments, the phase change element 310 is further covered by a protective layer 312. The protective layer 312 is allocated between the phase change element 310 and the via holes 308. The phase change element 310 may comprise GeSbTe (as known as GST), or any other compound having phase change capability. The protective layer 312 may comprise TiN or Ti/TiN or other similar compounds.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded to the broadest interpretation so as to encompass all such modifications and similar arrangements.

What is claimed is:

1. A phase change memory, comprising:
a top electrode;
a phase change element;
a plurality of via holes, allocated between the top electrode and the phase change element;
a first heater, a second heater, a third heater and a fourth heater, aiming at different regions of the phase change element, wherein the aimed regions of the phase change element form a 2×2 storage array;
a first bottom electrode, a second bottom electrode, a third bottom electrode and a fourth bottom electrode, coupled to the first, second, third and fourth heaters, respectively; and
a first transistor, a second transistor, a third transistor and a fourth transistor, coupled to the first, second, third and fourth bottom electrodes, respectively, and each of the transistors comprising a first terminal coupled to the corresponding bottom electrode, wherein the first transistor further comprises a second terminal receiving a first bit line signal and a control terminal receiving a first word line signal, the second transistor further comprises a second terminal receiving a second bit line signal and a control terminal receiving the first word line signal, the third transistor further comprises a second terminal receiving the first bit line signal and a control terminal receiving a second word line signal, and the fourth transistor further comprises a second terminal receiving the second bit line signal and a control terminal receiving the second word line signal.

2. The phase change memory as claimed in claim 1, wherein the top electrode is coupled to a reference voltage source.

3. The phase change memory as claimed in claim 1, wherein the material of the phase change element comprises GeSbTe.

4. The phase change memory as claimed in claim 1, wherein the phase change element is further covered by a protective layer that is allocated between the phase change element and the via holes.

5. The phase change memory as claimed in claim 4, wherein the material of the protective layer comprises TiN or Ti/TiN.

6. A phase change memory, comprising:
a top electrode;
a phase change element;
a plurality of via holes, allocated between the top electrode and the phase change element;
a plurality of heaters, aiming at different regions of the phase change element;
a plurality of bottom electrode, having a one-to-one relationship with the heaters and coupled to the corresponding heaters;
a plurality of transistors, having a one-to-one relationship with the bottom electrodes and each of the transistors comprising a first terminal, a second terminal and a control terminal, wherein the transistors are coupled to the corresponding bottom electrodes via the first terminals, the second terminals of the transistors are used for receiving the bit line signals of the phase change memory, and the control terminals of the transistors are used for receiving the word line signal of the phase change memory;
wherein each of the aimed regions of the phase change element represents one storage cell of the phase change memory.

7. The phase change memory as claimed in claim 6, wherein the top electrode is coupled to a reference voltage source.

8. The phase change memory as claimed in claim 6, wherein the material of the phase change element comprises GeSbTe.

9. The phase change memory as claimed in claim 6, wherein the phase change element is further covered with a protective layer that is allocated between the phase change element and the via holes.

10. The phase change memory as claimed in claim 9, wherein the material of the protective layer comprises TiN or Ti/TiN.
